(19) United States
(12) Patent Application Publication
(10) Pub. No.: US 2026/0135347 A1
(43) Pub. Date: May 14, 2026

(54) PULSE CONTROL DEVICE AND LASER PROCESSING SYSTEM

(71) Applicant: INDUSTRIAL TECHNOLOGY RESEARCH INSTITUTE, Hsinchu (TW)

(72) Inventors: Jia-You WANG, Kaohsiung City (TW); Fu-Shun HO, Tainan City (TW); Shang-Yu HSU, Tainan City (TW); Yu-Cheng SONG, Tainan City (TW)

(73) Assignee: INDUSTRIAL TECHNOLOGY RESEARCH INSTITUTE, Hsinchu (TW)

(21) Appl. No.: 18/974,265

(22) Filed: Dec. 9, 2024

(30) Foreign Application Priority Data
Nov. 8, 2024 (TW) 113142990

(51) Int. Cl. H01S 5/062; H01S 5/00; H01S 5/042; H03K 5/05

(52) U.S. Cl. CPC H01S 5/06216; H01S 5/005; H01S 5/0428; H03K 5/05

(57) ABSTRACT

A pulse control device and laser processing system including the same are applicable for a plurality of seed laser drivers. The pulse control device includes a plurality of pulse generation circuits and a pulse delay adjustment circuit. The pulse generation circuits are configured to generate a plurality of pulse signals according to a plurality of pulse setting data, respectively, and each of the plurality of pulse setting data at least includes a pulse frequency. The pulse delay adjustment circuit is connected to the pulse generation circuits and configured to control an interval time between the pulse signals according to a reference signal, and outputs a plurality of adjusted pulse signals to the seed laser drivers, respectively. The reference signal is one of pulse signals or a standard signal, and duration corresponding to the pulse frequency in each of the plurality of pulse setting data is different from the interval time.

### CROSS-REFERENCE TO RELATED APPLICATIONS

The present application is based on, and claims priority from, Taiwan (International) application No. 113142990, filed on Nov. 8, 2024, the disclosure of which is hereby incorporated by reference herein in its entirety.

### BACKGROUND

### 1. Technical Field

This disclosure relates to a pulse control device and laser processing system.

### 2. Related Art

Semiconductor laser processing is a precision technology utilizing laser diodes as a light source. These lasers generate coherent, monochromatic beams through the recombination of electrons and holes in semiconductor materials, amplified within an optical resonator. Known for their high efficiency, compact size, and wavelength versatility, semiconductor lasers are widely used in electronics, medical devices, optics, telecommunications, and material science. Their ability to deliver focused, high-intensity beams makes them ideal for tasks like cutting, engraving, welding, and surface modification, while also reducing the risk of thermal distortion.

### SUMMARY

According to an embodiment of this disclosure, a pulse control device, applicable for a plurality of seed laser drivers, comprises a plurality of pulse generation circuits and a pulse delay adjustment circuit. The plurality of pulse generation circuits is configured to generate a plurality of pulse signals according to a plurality of pulse setting data, respectively, and each of the plurality of pulse setting data at least includes a pulse frequency. The pulse delay adjustment circuit is connected to the plurality of pulse generation circuits and configured to control an interval time between the plurality of pulse signals according to a reference signal, and outputs a plurality of adjusted pulse signals to the plurality of seed laser drivers, respectively. The reference signal is one of the plurality of pulse signals or a standard signal, and a duration corresponding to the pulse frequency in each of the plurality of pulse setting data is different from the interval time.

According to one or more embodiment of this disclosure, a laser processing system, for surface processing of a material to be processed, comprises a pulse control device, a plurality of seed laser drivers and a plurality of seed laser sources. The pulse control device comprises a plurality of pulse generation circuits and a pulse delay adjustment circuit. The plurality of pulse generation circuits is configured to generate a plurality of pulse signals according to a plurality of pulse setting data, respectively, and each of the plurality of pulse setting data at least includes a pulse frequency. The pulse delay adjustment circuit is connected to the plurality of pulse generation circuits and configured to control an interval time between the plurality of pulse signals according to a reference signal, and outputs a plurality of adjusted pulse signals, respectively. The plurality of seed laser drivers is connected to the pulse delay adjustment circuit, connected to the plurality of seed laser sources, respectively, and configured to receive the plurality of adjusted pulse signals, respectively, and drive the plurality of seed laser sources to output a plurality of pulsed light beams according to the plurality of adjusted pulse signals, wherein the reference signal is one of the plurality of pulse signals or a standard signal, and a duration corresponding to the pulse frequency in each of the plurality of pulse setting data is different from the interval time.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a block diagram illustrating a laser processing system and a pulse control device thereof according to an embodiment of the present disclosure;

FIG. 2 is a block diagram illustrating a pulse control device according to another embodiment of the present disclosure;

FIG. 3 is a block diagram illustrating a pulse control device according to still another embodiment of the present disclosure;

FIG. 4 is a schematic diagram illustrating the application architecture of a laser processing system according to an embodiment of the present disclosure;

FIG. 5 is a schematic diagram illustrating the pulsed light beams output by a laser processing system according to an embodiment of the present disclosure; and

FIG. 6 illustrates the processing effects on a material generated by a laser processing system according to an embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

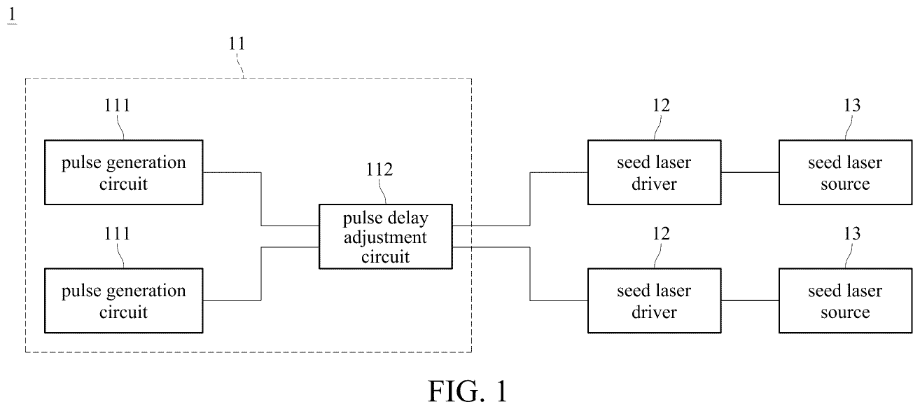

The pulse control device and laser processing system proposed in this disclosure may be configured to process a material to be processed, particularly for surface processing. FIG. 1 is a block diagram illustrating a laser processing system and a pulse control device thereof according to an embodiment of the present disclosure. As shown in FIG. 1, a laser processing system 1 comprises a pulse control device 11, a plurality of seed laser drivers 12 and a plurality of seed laser sources 13. The pulse control device 11 includes a plurality of pulse generation circuits 111 and a pulse delay adjustment circuit 112. The plurality of pulse generation circuits 111 are configured to generate a plurality of pulse signals according to a plurality of pulse setting data, respectively, and each of the plurality of pulse setting data at least includes a pulse frequency. The pulse delay adjustment circuit 112 is connected to the plurality of pulse generation circuits 111 via a wired or wireless mean, and configured to control an interval time between the plurality of pulse signals according to a reference signal, and output the adjusted pulse signals to the plurality of seed laser drivers 12, respectively. The reference signal may be one of the plurality of pulse signals or a standard signal, and the duration corresponding to the pulse frequency in each of the plurality of pulse setting data differs from the interval time. The plurality of seed laser drivers 12 are connected to the pulse delay adjustment circuit 112 via a wired mean and connected to the plurality of seed laser sources 13 via a wired mean, respectively. The plurality of seed laser drivers 12 are configured to receive the adjusted pulse signals, respectively, and drive the plurality of seed laser sources 13 to output a plurality of pulsed light beams according to the adjusted pulse signals.

In this embodiment, each pulse generation circuit 111 may generate a pulse signal based on the respective pulse setting data to drive subsequent seed laser drivers. Specifically, in addition to the aforementioned pulse frequency (repetition rate), the pulse setting data may further include one or both of the pulse width and total power, but are not limited thereto. These pulse setting data may be provided by a master control device (e.g., a computer apparatus), and may be set according to actual processing requirements (e.g., the characteristics of the material to be processed). The master control device may include one or more processing/control units with functions such as data reception, recording, computation, storage, and output. Examples of the processing/control unit include a microcontroller, a central processing unit (CPU), a graphic processing unit (GPU), a programmable logic controller (PLC), or any combination thereof. Alternatively, the pulse generation circuit 111 may include a user interface, allowing the pulse setting data to be set by an operator through the user interface.

For example, in an application scenario where a specific pulse energy is required, the relationship between pulse frequency (repetition rate), total power, and pulse energy may be used for setting (e.g., Equation 1). In an application scenario where a specific pulse peak power is required, the relationship between pulse energy and pulse width may be used for setting (e.g., Equation 2).

Total Power=Pulse Energy×Repetition Rate. Equation 1:

Pulse Peak Power=C×Pulse Energy/Pulse Width, wherein C is a shape parameter associated with the pulse signal. Equation 2:

Furthermore, each pulse generation circuit 111 may generate pulse signals based on the respective processing requirements using different pulse setting data. This means that the pulse signals generated by the pulse generation circuits 111 may have different pulse frequencies, pulse widths, and/or total power. In an embodiment, the pulse signals generated by the pulse generation circuits 111 may have the same pulse frequency (repetition rate), and the subsequent pulse delay adjustment circuit 112 may adjust the delays of the pulse signals from the pulse generation circuits 111 to achieve a consistent pulse signal delay effect.

The pulse delay adjustment circuit 112 may include a delayer, and the delayer may take one of the plurality of pulse signals as a reference signal and delay the remaining one or more pulse signals using the reference signal as a basis according to a plurality of delay parameters, wherein an absolute difference between the plurality of delay parameters corresponds to the interval time. After adjusting the interval time between the plurality of pulse signals, the pulse delay adjustment circuit 112 may output the adjusted pulse signals to the plurality of seed laser drivers 12, respectively. Moreover, the pulse delay adjustment circuit 112 may be implemented in other forms, which are further described in other embodiments below. Although FIG. 1 shows two pulse generation circuits 111 as an example, the disclosure is not limited to this. The pulse delay adjustment circuit 112 may also be connected to more pulse generation circuits 111 and adjust the delay of their pulse signals.

The seed laser driver 12 may electrically drive the seed laser source 13 at the backend according to the pulse signal provided by the pulse control device 11. Specifically, the seed laser driver 12 may drive the seed laser source 13 to output pulsed light beams that conforms to the pulse setting data (pulse frequency, pulse energy, total power) based on the pulse signal. The seed laser source 13 may be, for example, a light-emitting diode. Particularly, since the pulse signals are delay-controlled by the pulse delay adjustment circuit 112, the plurality of pulsed light beams output from the plurality of seed laser sources 13 may have corresponding time intervals therebetween. Temporally, the time interval between the first pulsed light beam and the last pulsed light beam may correspond to the above-mentioned interval time. In an embodiment, the seed laser source 13 refer to a laser source capable of emitting laser light with relatively low energy for subsequent optical amplifiers or optical resonators. The pulse control device 11 in an embodiment of the disclosure is particularly applicable for driving the plurality of seed laser sources 13 via the plurality of seed laser drivers 12.

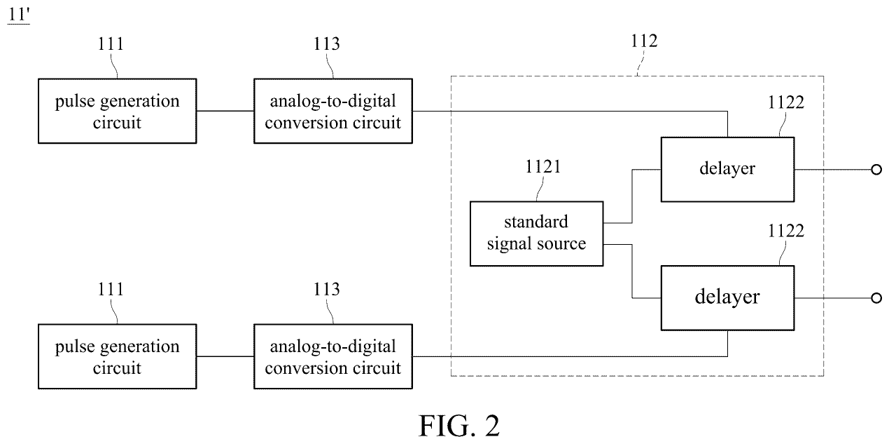

Please refer to FIG. 2, which is a block diagram illustrating a pulse control device according to another embodiment of the present disclosure. As shown in FIG. 2, in this embodiment, a pulse control device 11′ may optionally include a plurality of analog-to-digital conversion circuits 113 connected to the plurality of pulse generation circuits 111, respectively, connected to the pulse delay adjustment circuit 112, and configured to shape the pulse signals into square waves and digitize the pulse signals, respectively. For example, the analog-to-digital conversion circuit 113 may be implemented by an analog-to-digital converter (ADC). Alternatively, the analog-to-digital conversion circuit 113 may include an operational amplifier, a comparator, and/or a transistor-level component, etc. After receiving the pulse signal (analog signal) from the pulse generation circuit 111, the analog-to-digital conversion circuit 113 may first shape the pulse signal into a square wave to facilitate subsequent operation of digitization, and then digitize the square wave-shaped pulse signal for the subsequent pulse delay adjustment circuit 112. It is worth noting that while FIG. 2 illustrates that each pulse generation circuit 111 corresponds to one analog-to-digital conversion circuit 113; however, the plurality of pulse generation circuits 111 may also share one analog-to-digital conversion circuit 113, and the disclosure is not limited to this.

In this embodiment, the pulse delay adjustment circuit 112 may include a standard signal source 1121 and a plurality of delayers 1122. The standard signal source 1121 is configured to provide the standard signal. The plurality of delayers 1122 are connected to the standard signal source 1121 via a wired mean, and through the analog-to-digital conversion circuits 113 connected to the plurality of pulse generation circuits 111, respectively. The plurality of delayers 1122 are configured to delay the plurality of pulse signals using the standard signal as a basis according to a plurality of delay parameters, respectively, wherein an absolute difference between the plurality of delay parameters corresponds to the interval time. Specifically, the standard signal source 1121 may provide a standard clock signal as the timing reference for each pulse signal. Each delayer 1122 may align the pulse signal with the standard signal, and delays the pulse signal according to the respective delay parameter. For example, the first pulse signal may be delayed by 10 nanoseconds relative to the standard signal, and the second pulse signal may be delayed by 25 nanoseconds relative to the standard signal. In this way, the interval time between the first pulse signal and second pulse signal may be 15 nanoseconds. Moreover, compared to the embodiment in FIG. 1, although this embodiment describes the pulse control device 11′ that includes the analog-to-digital conversion circuit 113 and pulse delay adjustment circuit 112 with a standard signal source and a plurality of delayers; however, this embodiment is merely exemplary. In other embodiments, the analog-to-digital conversion circuit 113 may operate with a pulse delay adjustment circuit 112 containing a single delayer to achieve similar delay effects.

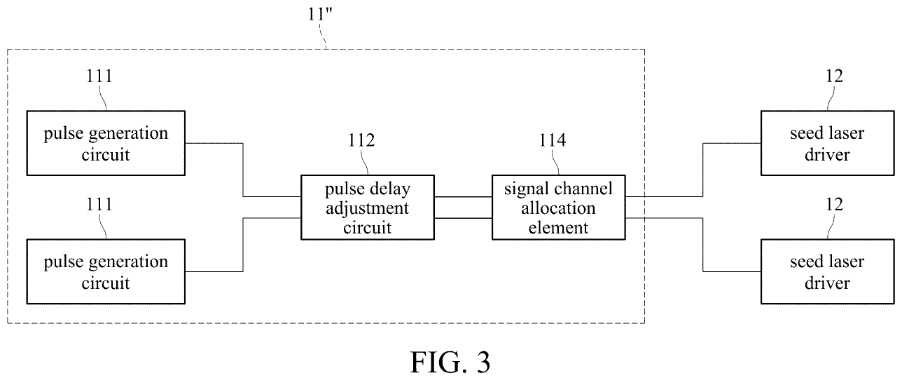

Please refer to FIG. 3, which is a block diagram illustrating a pulse control device according to still another embodiment of the present disclosure. As shown in FIG. 3, in this embodiment, a pulse control device 11″ may optionally include a signal channel allocation element 114 connected to the pulse delay adjustment circuit 112 and the plurality of seed laser drivers 12, and configured to isolate the adjusted pulse signals from external noise, and to provide the adjusted pulse signals to the plurality of seed laser drivers 12, respectively. For example, the signal channel allocation element 114 may include a plurality of shielded cables connected to the plurality of seed laser drivers 12, respectively, wherein each of the shielded cables has a common conductive layer around the center conductor to implement the function of electromagnetic shielding. Therefore, this may effectively reduce external noise interference and simultaneously reduce the radiation of transmitted signals to outside that might interfere with other devices. Particularly, after the precise interval adjustment by the pulse delay adjustment circuit 112, the signal channel allocation element 114 may further ensure that the interval time between the plurality of pulsed light beams generated by the plurality of seed laser drivers 12 would not generate deviation due to noise interference during the transmission process. Moreover, the embodiments illustrated in FIG. 1 to FIG. 3 may be combined with each other, and various combinations are not individually exemplified here.

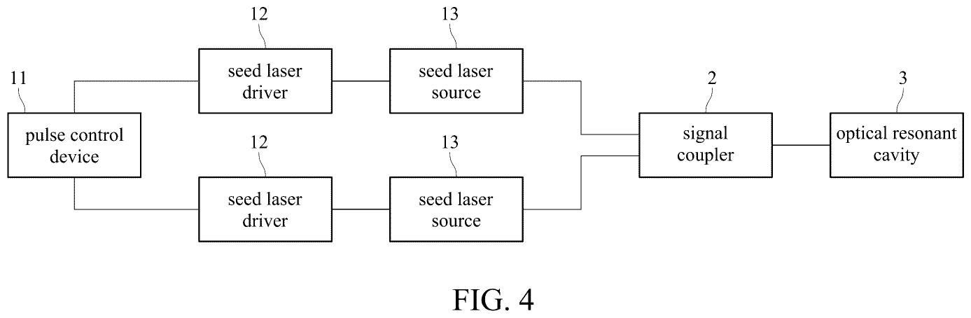

Please refer to FIG. 4, which is a schematic diagram illustrating the application architecture of a laser processing system according to an embodiment of the present disclosure. As shown in FIG. 4, based on the previous embodiments, the laser processing system including the pulse control device 11, seed laser driver 12 and seed laser source 13 may form a master oscillator power amplifier (MOPA) architecture with a signal coupler 2 and an optical resonator 3. In this MOPA architecture, the plurality of seed laser sources 13 output a plurality of pulsed light beams with time intervals between each other, and these pulsed light beams are coupled by the signal coupler 2 and then input to the optical resonator 3 for amplification, and ultimately, high-power processing pulsed light beams are output for surface processing to the material to be processed. Specifically, the plurality of seed laser sources 13 may deliver the plurality of pulsed light beams to the signal coupler 2 via optical fibers, respectively. The signal coupler 2 may be, for example, a fiber-based beam combiner, and after combining a plurality of temporally staggered pulsed light beams into a single pulsed light sequence, transmits the pulsed light sequence to the optical resonator 3 via an optical fiber for optical amplification. The optical resonator 3 may be, for example, an optical parametric oscillator (OPO) or other form of optical resonator.

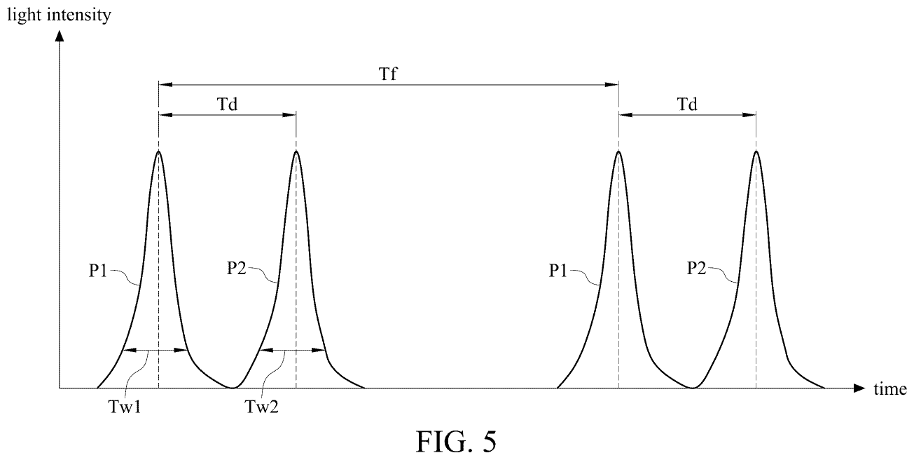

Please refer to FIG. 5 in combination with FIG. 1. FIG. 5 is a schematic diagram illustrating the pulsed light beams output by a laser processing system according to an embodiment of the present disclosure. As shown in FIG. 5, the first pulsed light beam P1 is a light signal output by a seed laser source 13, and the second pulsed light beam P2 is a light signal output by another seed laser source 13. In terms of timing, the pulse frequency of the first pulsed light beam P1 (and the second pulsed light beam P2) corresponds to a pulse period Tf. The first pulsed light beam P1 may have a first pulse width Tw1, the second pulsed light beam P2 may have a second pulse width Tw2, and an interval time Td may exist between the first pulsed light beam P1 and the second pulsed light beam P2. In this embodiment, the duration (the pulse period Tf) corresponding to the pulse frequency in each of the plurality of pulse setting data is greater than the interval time Td. Moreover, the interval time Td is greater than the pulse width in each of the plurality of the pulse setting data, i.e., the interval time Td is greater than the first pulse width Tw1 and the second pulse width Tw2. Therefore, the first pulsed light beam P1 and the second pulsed light beam P2 may be separated from each other due to the interval time Td so as to achieve a segmented processing effect.

Conventionally, a long time gap between two pulses during pulsed laser processing prevents sufficient thermal accumulation in the heat-affected zone, resulting in poor processing effects. However, increasing the repetition rate to shorten the interval often result in the reduction of pulse energy. Conversely, raising the power to enhance removal ability may lead to excessive surface roughness at the bottom of the processed features. By contrast, adopting the first pulsed light beam P1 of the laser processing technology of the present disclosure may be configured to pre-melt the material to be processed, when the material to be processed is heated by the first pulsed light beam P1, properties (e.g., light absorption rate) of which may change. The second pulsed light beam P2 may be used for the primary processing, such as laser ablation, to perform surface processing of the material to be processed. In this way, the appropriate pulse setting data (including pulse frequency, pulse width, and total power) may be selected in the application to generate the first pulsed light beam P1 to change the state of the material to be processed, and adjust the pulse delay through the pulse with high-speed adjustment capability to provide the second pulsed light beam P2 at a time point after the given interval time Td, so that the processing efficiency of the second pulsed light beam P2 to the material to be processed may be greatly improved and the overall laser processing effect is improved. In an embodiment, the interval time Td may be 10 nanoseconds to 100 nanoseconds.

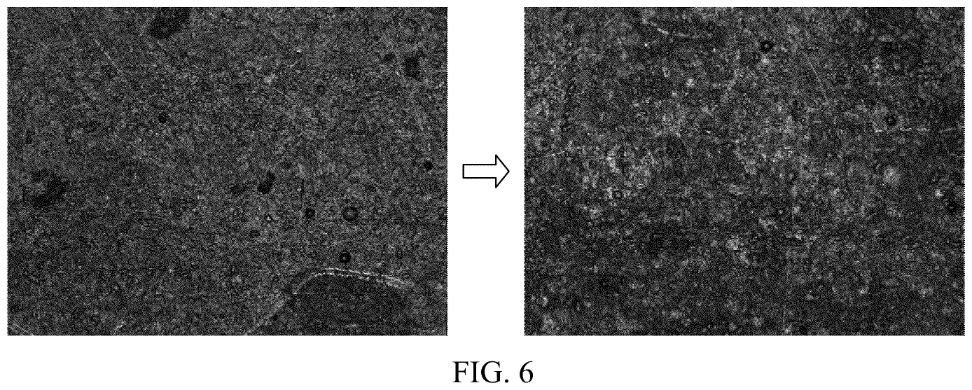

Please refer to FIG. 6, which illustrates the processing effects on a material generated by a laser processing system according to an embodiment of the present disclosure. The left half part of FIG. 6 shows the surface processing effect on a copper substrate using a conventional laser processing method; the right half part of FIG. 6 shows the surface processing effect on a copper substrate using the laser processing method in an embodiment of the present disclosure. The comparison of FIG. 6 is based on the identical laser setting data, specifically including a pulse frequency of 30 kHz, a pulse width corresponding to 100 nanoseconds, and a spacing between pulses corresponding to 15 nanoseconds. As shown in FIG. 6 and Table 1 below, Table 1 provides a comparison of surface roughness after material processing using conventional and the proposed laser processing methods. It may be seen that adopting the pulse control device and laser processing system of the embodiment of the present disclosure may significantly improve surface uniformity on the copper substrate compared to the conventional processing method.

TABLE 1

| | Sa (μm) | Sz (μm) | Str (μm) |
|---|---|---|---|
| Conventional Processing Method | | | |
| Average Roughness | 1.8057 | 16.7858 | 0.350 |
| Proposed Processing Method | | | |
| Average Roughness | 0.6364 | 12.9004 | 0.356 |

In view of the above description, the pulse control device and laser processing system disclosed in the present disclosure may enable the pulse output of one seed laser source relative to the pulse output of another seed laser source to have a delayed processing time corresponding to the interval time by controlling the interval time between a plurality of driving signals of a plurality of seed laser drivers. Therefore, this approach may shorten the time interval between pulse outputs from the seed laser sources without increasing the pulse frequency of a single source or adding extra pulse energy. As a result, the thermal accumulation effect during material processing may be effectively enhanced, improving surface uniformity in the fabrication process, allowing for increased circuit density, and ultimately enhancing the overall laser processing performance.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. A pulse control device, applicable for a plurality of seed laser drivers, comprising:
a plurality of pulse generation circuits configured to generate a plurality of pulse signals according to a plurality of pulse setting data, respectively, wherein each of the plurality of pulse setting data at least includes a pulse frequency; and
a pulse delay adjustment circuit connected to the plurality of pulse generation circuits, and configured to control an interval time between the plurality of pulse signals according to a reference signal, and output a plurality of adjusted pulse signals to the plurality of seed laser drivers, respectively,
wherein the reference signal is one of the plurality of pulse signals or a standard signal, and a duration corresponding to the pulse frequency in each of the plurality of pulse setting data is different from the interval time.

2. The pulse control device according to claim 1, wherein the duration corresponding to the pulse frequency in each of the plurality of pulse setting data is greater than the interval time.

3. The pulse control device according to claim 1, wherein each of the plurality of pulse setting data further comprises a pulse width, and the interval time is greater than the pulse width of each of the plurality of pulse setting data.

4. The pulse control device according to claim 1, wherein the interval time is 10 nanoseconds to 100 nanoseconds.

5. The pulse control device according to claim 1, further comprising an analog-to-digital conversion circuit connected to the plurality of pulse generation circuits and the pulse delay adjustment circuit, and configured to shape the plurality of pulse signals into square waves and digitize the plurality of pulse signals.

6. The pulse control device according to claim 1, wherein the pulse delay adjustment circuit comprises:
a standard signal source configured to provide the standard signal; and
a plurality of delayer connected to the standard signal source, connected to the plurality of pulse generation circuits, respectively, and configured to delay the plurality of pulse signals using the standard signal as a basis according to a plurality of delay parameters, respectively, wherein an absolute difference between the plurality of delay parameters corresponds to the interval time.

7. The pulse control device according to claim 1, wherein the pulse delay adjustment circuit is configured to use one of the plurality of pulse signals as the reference signal, and delay other of the plurality of pulse signals using the reference signal as a basis according to a plurality of delay parameters, wherein an absolute difference between the plurality of delay parameters corresponds to the interval time.

8. The pulse control device according to claim 1, further comprising a signal channel allocation element connected to the pulse delay adjustment circuit and the plurality of seed laser drivers, and configured to isolate the plurality of adjusted pulse signals from external noise, and to provide the plurality of adjusted pulse signals to the plurality of seed laser drivers, respectively.

9. A laser processing system, for surface processing of a material to be processed, comprising:
a pulse control device comprising:
a plurality of pulse generation circuits configured to generate a plurality of pulse signals according to a plurality of pulse setting data, respectively, wherein each of the plurality of pulse setting data at least includes a pulse frequency; and
a pulse delay adjustment circuit connected to the plurality of pulse generation circuits and configured to control an interval time between the plurality of pulse signals according to a reference signal, and outputting a plurality of adjusted pulse signals, respectively,
a plurality of seed laser sources; and
a plurality of seed laser drivers, connected to the pulse delay adjustment circuit, connected to the plurality of seed laser sources, respectively, and configured to receive the plurality of adjusted pulse signals, respectively, and drive the plurality of seed laser sources to output a plurality of pulsed light beams according to the plurality of adjusted pulse signals,
wherein the reference signal is one of the plurality of pulse signals or a standard signal, and a duration corresponding to the pulse frequency in each of the plurality of pulse setting data is different from the interval time.

10. The laser processing system according to claim 9, wherein the duration corresponding to the pulse frequency in each of the plurality of pulse setting data is greater than the interval time.

11. The laser processing system according to claim 9, wherein each of the plurality of pulse setting data further comprises a pulse width, and the interval time is greater than the pulse width of each of the plurality of pulse setting data.

12. The laser processing system according to claim 9, wherein the interval time is 10 nanoseconds to 100 nanoseconds.

13. The laser processing system according to claim 9, wherein the pulse control device further comprises an analog-to-digital conversion circuit connected to the plurality of pulse generation circuits and the pulse delay adjustment circuit, and the analog-to-digital conversion circuit configured to shape the plurality of pulse signals into square waves and digitize the plurality of pulse signals.

14. The laser processing system according to claim 9 wherein the pulse delay adjustment circuit comprises:
a standard signal source configured to provide the standard signal; and
a plurality of delayer connected to the standard signal source, connected to the plurality of pulse generation circuits, respectively, and configured to delay the plurality of pulse signals using the standard signal as a basis according to a plurality of delay parameters, respectively, wherein an absolute difference between the plurality of delay parameters corresponds to the interval time.

15. The laser processing system according to claim 9, wherein the pulse delay adjustment circuit is configured to use one of the plurality of pulse signals as the reference signal, and delay other of the plurality of pulse signals using the reference signal as a basis according to a plurality of delay parameters, wherein an absolute difference between the plurality of delay parameters corresponds to the interval time.

16. The laser processing system according to claim 9, wherein the pulse control device further comprises a signal channel allocation element connected to the pulse delay adjustment circuit and the plurality of seed laser drivers, and configured to isolate the plurality of adjusted pulse signals from external noise and provide the plurality of adjusted pulse signals to the plurality of seed laser drivers, respectively.
